(19) United States
(12) Patent Application Publication
(10) Pub. No.: US 2024/0379353 A1
(43) Pub. Date: Nov. 14, 2024

(54) METHOD OF FORMING AN EPITAXIAL STACK AND SUBSTRATE PROCESSING APPARATUS FOR FORMING THE SAME

(71) Applicant: ASM IP Holding B.V., Almere (NL)

(72) Inventors: Wonjong Kim, Leuven (BE); Rami Khazaka, Leuven (BE)

(21) Appl. No.: 18/659,368

(22) Filed: May 9, 2024

Related U.S. Application Data
(60) Provisional application No. 63/465,506, filed on May 10, 2023.

(51) Int. Cl. H01L 21/02; C30B 25/02

(52) U.S. Cl. CPC H01L 21/0262; C30B 25/02; H01L 21/02532

(57) ABSTRACT

A method for epitaxially forming an epitaxial stack on a substrate is disclosed. Embodiments of the presently described method comprise performing a plurality of deposition cycles to form the epitaxial stack, whereby each of the deposition cycles comprises deposition pulses to form the individual epitaxial layers of the epitaxial stack.

### CROSS-REFERENCE TO RELATED APPLICATION(S)

This application claims the benefit of U.S. Provisional Application 63/465,506 filed on May 10, 2023, the entire contents of which are incorporated herein by reference.

### FIELD OF INVENTION

The present disclosure relates to a method of forming an epitaxial stack and a substrate processing apparatus for forming the epitaxial stack. More specifically, the disclosure relates to a method of and a substrate processing apparatus for forming a silicon/silicon germanium epitaxial stack on a substrate.

### BACKGROUND OF THE DISCLOSURE

Due to the continuing advancements in semiconductor industry, three dimensional transistors are considered as becoming the next generation devices. Among them nanosheet field effect transistors are considered promising due to their ability to provide reduced leakage currents and high driving currents. This may therefore, increase the focus on the manufacturing, thus the processing, of these devices.

Among the three dimensional transistors, vertically stacked nanosheet based complementary field effect transistors (CFET) are the ones where n-MOS and p-MOS devices are placed on top of each other. This may be realized through a stack of silicon germanium epitaxial layers and silicon epitaxial layers, whereby the channel may be implemented by removing the silicon germanium layer by performing a selective etching process

One of the challenges that may be associated with the manufacturing of CFETs is the ability to obtain a fully strained silicon germanium-silicon/Si epitaxial stack without defects in order to avoid channel degradation.

Therefore, there may be a need to provide methods that are capable of realizing the formation of epitaxial stacks with improved layer properties on the substrate.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter

It may be an object of the present disclosure to enable growth of an epitaxial stack on a substrate.

In a first aspect, the present disclosure relates to a method of forming an epitaxial stack. The method may comprise providing a substrate to a process chamber. The method may further comprise performing a plurality of deposition cycles, thereby forming the epitaxial stack on the substrate. The epitaxial stack may comprise a plurality of first epitaxial airs. Each first epitaxial pair may comprise a first epitaxial layer and a second epitaxial layer. The first epitaxial layer and the second epitaxial layer of each first epitaxial pair may comprise at least a first Group-IV semiconductor material and the second epitaxial layer of each first epitaxial pair may further comprise a second Group-IV semiconductor material that may be different from the first Group-IV semiconductor material. Each of the plurality of deposition cycles may be performed at a pressure value of less than 10 Torr.

The method according to embodiments of the first aspect of the present disclosure may allow for forming an epitaxial stack. It may advantageously allow for forming an epitaxial stack comprising Si₁₋ₓGeₓ and Si epitaxial layers.

It may further be an advantage of embodiments of the first aspect that an epitaxial stack comprising Si₁₋ₓGeₓ and Si epitaxial layers with reduced defects may be obtained. This epitaxial stack may advantageously be suitable for manufacturing gate-all-around field effect transistor (GAA-FET) devices. Particularly, this epitaxial stack may be advantageous for manufacturing complimentary field effect transistor (CFET) devices.

It may be an advantage of embodiments of the first aspect that a fully strained epitaxial stack of Si₁₋ₓGeₓ/Si epitaxial layers may be formed at lower process temperatures, such as for example, lower than 600° C.

It may further be an advantage of embodiments of the first aspect that particle formation during the formation of the epitaxial stack may be reduced.

It may also be an advantage of embodiments of the first aspect that defect formation, such as for example, misfit dislocation defects during the formation of the epitaxial stack may be reduced.

It may further be an advantage of embodiments of the first aspect that an improved growth rate of the Si₁₋ₓGeₓ/Si epitaxial layers at lower process temperatures, such as for example, lower than 600° C., may be achieved.

It may further be an advantage of embodiments of the first aspect that thanks to the improved growth rate of the Si₁₋ₓGeₓ/Si epitaxial layers at lower process temperatures, a risk of having a loss of throughput of the process may be reduced.

In a second aspect, the present disclosure relates to a substrate processing apparatus. The substrate processing apparatus may be suitable for forming an epitaxial stack. The substrate processing apparatus may comprise a process chamber constructed and arranged to hold a substrate. The apparatus may comprise a silicon precursor storage module. The silicon precursor storage module may comprise a Si-containing precursor. The apparatus may further comprise a germanium precursor storage module. The germanium precursor storage module may comprise a Ge-containing precursor. The apparatus may also comprise a heater that may be configured to attain a process temperature in the process chamber and a pressure controller that maybe configured to attain process pressure in the process chamber. The apparatus may further comprise a controller. The controller may be connected to the silicon precursor storage module and to the germanium precursor storage module. The controller may be configured to execute instructions stored in a non-transitory computer readable medium to cause the substrate processing apparatus to form the epitaxial stack in the substrate in accordance with a method according to the embodiments of the first aspect of the present disclosure.

The substrate processing apparatus according to embodiments of the second aspect of the present disclosure may allow for growing an epitaxial stack on a substrate. It may particularly allow for growing a fully strained Si₁₋ₓGeₓ/Si epitaxial stack on the substrate.

It may be an advantage of embodiments of the second aspect that a risk for having process throughput loss, at lower process temperatures, such as for example, lower than 600° C., may be reduced.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure

Like reference numbers will be used for like elements in the drawings unless stated otherwise. Reference signs in the claims shall not be understood as limiting the scope.

FIG. 1a: Flowchart of an exemplary method according to embodiments of the first aspect of the present disclosure.

FIG. 1b: Flowchart of an embodiment according to the first aspect of the present disclosure.

FIG. 2a: A schematic drawing of an epitaxial stack according to an embodiment of the first aspect of the present disclosure.

FIG. 2b: A schematic drawing of an epitaxial stack according to another embodiment of the first aspect of the present disclosure.

FIG. 3a: Top view SEM images obtained after depositing a Si₁₋ₓGeₓ epitaxial layer on Si (100) surface at 40 Torr process chamber pressure and with a N₂ flow of 20 slm as carrier gas and with a GeH₄ flow of 800 sccm and with a Si₂H₆ flow at (1) 30 sccm, (b) 40 sccm, (3) 80 sccm and (4) 120 sccm.

FIG. 3b: Top view Scanning Electron Microscopy (SEM) images obtained after depositing a Si₁₋ₓGeₓ epitaxial layer on Si (100) surface at 3 Torr process chamber pressure and with a N₂ flow of 10 slm as carrier gas and with a SiH₄ flow of 40 sccm and with a GeH₄ flow at (1) 200 sccm, (b) 400 sccm, (3) 800 sccm and (4) 160 sccm.

FIG. 4a: Light scattering image for di-silane flow of 600 sccm.

FIG. 4b: Light Scattering image for di-silane flow of 100 sccm.

FIG. 5: High Resolution X-Ray Diffraction (HR-XRD) graph for an epitaxial stack of Si₁₋ₓGeₓ/Si with Si₁₋ₓGeₓ epitaxial layers having a differing Ge concentration in atomic % such as 20% and 40%.

FIG. 6: A schematic representation of a substrate processing apparatus according to embodiments of the second aspect of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

It is to be noticed that the term “comprising”, as used herein, should not be interpreted as being restricted to the means listed thereafter. It does not exclude other elements or steps. It is thus, to be interpreted as specifying the presence of the stated features, steps or components as referred to. However, it does not prevent one or more other steps, components, or features, or groups thereof from being present or being added.

Reference throughout the specification to “embodiments” in various places are not necessarily all referring to the same embodiment, but may. Furthermore, the particular features, structures or characteristics maybe combined in any suitable manner, as would be apparent to one of the ordinary skill in the art from the disclosure, in one or more embodiments.

Reference throughout the specification to “some embodiments” means that a particular structure, feature step described in connection with these embodiments is included in some of the embodiments of the present invention. Thus, phrases appearing such as “in some embodiments” in different places throughout the specification are not necessarily referring to the same collection of embodiments, but may.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may.

It is to be noticed that the term “comprise substantially” used in the claims refers that further components than those specifically mentioned can, but not necessarily have to, be present, namely those not materially affecting the essential characteristics of the material, compound, or composition referred to.

The terms first, second, third, and the like in the description and in the claims, are used for distinguishing between similar elements. They are not necessarily used for describing a sequence, either temporally, spatially, in ranking, or in any other manner. It is to be understood that the terms so used are interchangeable under appropriate circumstances and that the embodiments of the disclosure described herein are capable of operation in other sequences than described or illustrated herein.

The following terms are provided only to help in the understanding of the disclosure.

As used herein and unless provided otherwise, the term “purge gas” may refer to the gas that may be provided to the process chamber prior to and following after the deposition pulses.

As used herein and unless provided otherwise, the term “misfit dislocation density” may refer to the number of misfit dislocations per unit area.

As used herein and unless provided otherwise, the term “epitaxial pair” may refer to the a sub-set of epitaxial layers within the epitaxial stack, having two epitaxial layers being different from one another.

As used herein and unless provided otherwise, the term “epitaxial stack” may refer to the totality of the epitaxial pairs formed having at least nine pairs.

As used herein and unless provided otherwise, the term “fully strained” may refer to the in-plane lattice parameter matching with the lattice parameter of the layer or the substrate underneath.

As used herein and unless provided otherwise, the term “Si₁₋ₓGeₓ” may refer to a silicon germanium epitaxial layer, wherein x may be in a range from 10 atomic % to 50 atomic %.

The disclosure will now be described by a detailed description of several embodiments of the disclosure. It is clear that other embodiments of the disclosure can be configured according to the knowledge of persons skilled in the art in the absence of departure from the technical teaching of the disclosure. The disclosure is limited only by the terms of the claims included herein.

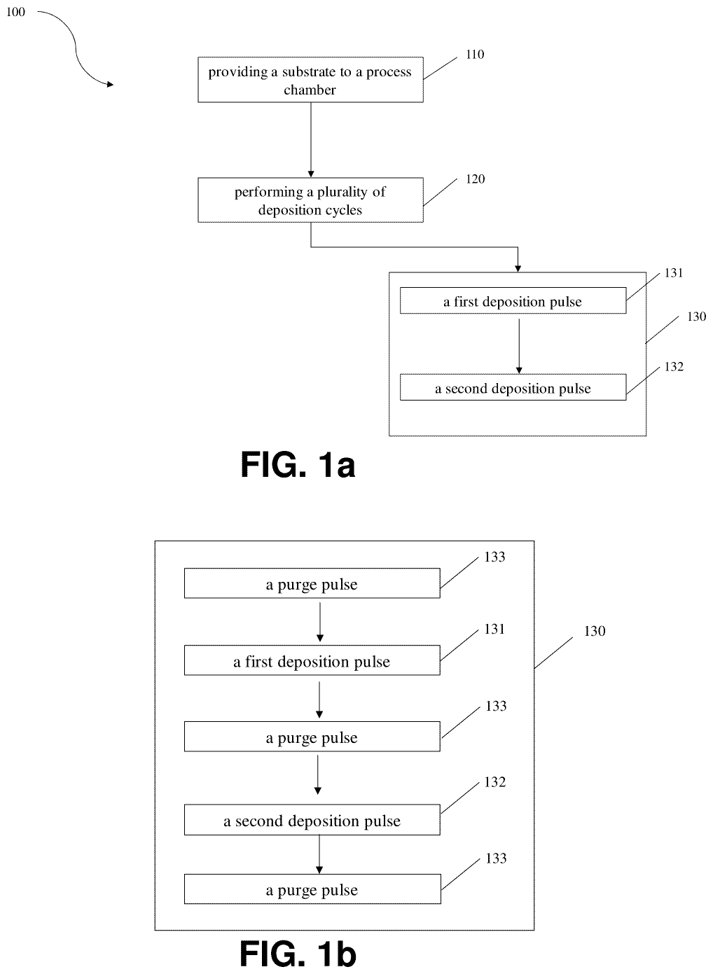

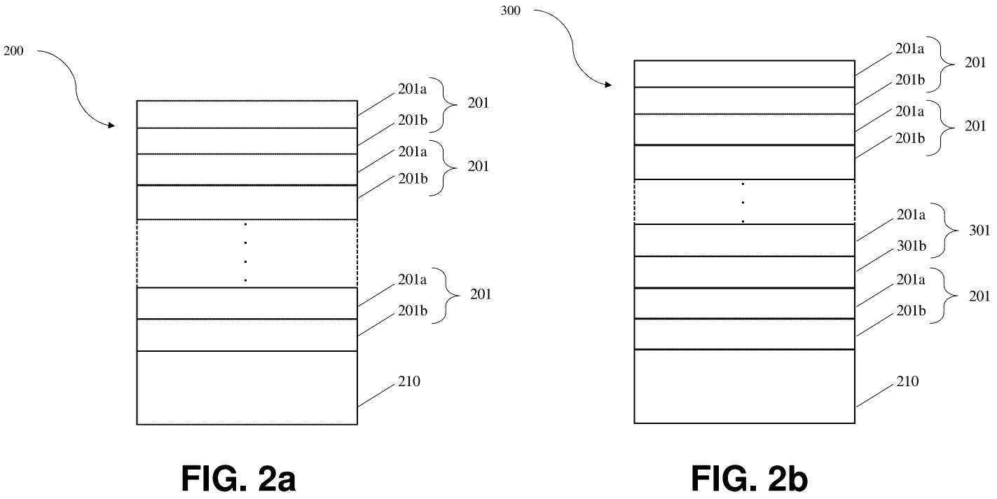

FIG. 1a shows a flowchart of an exemplary method according to embodiments of the first aspect of the present disclosure. FIG. 2a shows a schematic drawing of an epitaxial stack according to an embodiment of the first aspect of the present disclosure.

Described herein is a method of forming an epitaxial stack (200).

The method (100) may comprise providing (110) a substrate (210) to a process chamber. The process chamber may be comprised in a semiconductor processing apparatus. The semiconductor processing apparatus may be suitable for growing epitaxial layers.

In some embodiments, the process chamber may be one of at least two process chambers comprised in the semiconductor processing apparatus.

In some embodiments, the process chamber may be a single process chamber comprised in the semiconductor processing apparatus.

The method according to embodiments of the first aspect may be run in a single chamber; however, the same method may be run simultaneously in more than one process chamber of the semiconductor processing apparatus.

The method (100) may further comprise performing (120) a plurality of deposition cycles (130), thereby forming the epitaxial stack (200) on the substrate.

The epitaxial stack (200) may comprise a plurality of first epitaxial pairs (201). Each first epitaxial pair (201) may comprise a first epitaxial layer (201a) and a second epitaxial layer (201b). The first epitaxial layer (201a) and the second epitaxial layer (201b) of each first epitaxial pair (201) may comprise at least a first Group-IV semiconductor material. The second epitaxial layer (201b) of each first epitaxial pair (201) may further comprise a second Group-IV semiconductor material that may be different from the first semiconductor Group-IV semiconductor material. Each of the plurality of deposition cycles (130) may be performed at a pressure value less than 10 Torr.

In embodiments, each of the plurality of deposition cycles (130) may be performed at a pressure value in a range of about 0.1 Torr to about 10 Torr.

In embodiments, each of the plurality of deposition cycles (130) may be performed at a pressure value in a range of about 1 Torr to about 5 Torr.

The method according to embodiments of the first aspect may allow for forming an epitaxial stack (200) that may comprise differing epitaxial layers (201a, 201b). Thanks to the reduced pressure in the process chamber during the growth of the epitaxial stack (200), a reduced particle formation and a reduced defect formation may be achieved. This may be further advantageous for using such an epitaxial stack in the manufacturing of GAA-FET devices, particularly when the channel is in the form of a sheet, such as for example nanosheet-FET or CFET. This may be due to the fact that presence of particles and/or defects in the epitaxial stack may adversely influence device characteristics such as for example leakage current, threshold voltage. The presence of particles may further have an influence on the following processing steps such as for example, deposition, lithography and etch. This may be critical when these particles and/or defects are formed, particularly, in the layers of the epitaxial stack (200) that will later become the channel of such devices. Therefore, reduction in the formation and thus, the presence of particles and/or defects in the epitaxial stack may make the use of such an epitaxial stack (200) advantageous for the manufacturing of such devices.

In some embodiments, each of the plurality of deposition cycles (130) may be performed at a pressure value of about 3 Torr with +/−1 Torr change in pressure.

In embodiments, each deposition cycle (130) of the plurality of deposition cycles may comprise a first deposition pulse (131) and a second deposition pulse (132).

The first deposition pulse (131) may comprise providing a first Group-IV semiconductor material precursor gas. In this way, the first epitaxial layer may be formed (201a). The second deposition pulse (132) may comprise providing the first Group-IV semiconductor material precursor gas and may further comprise providing a second Group-IV semiconductor material precursor gas. In this way, the second epitaxial layer (201b) may be formed. The second Group-IV semiconductor material precursor gas may be different than the first Group-IV semiconductor material precursor gas.

Each deposition cycle (130) of the plurality of deposition cycles may thus, enable the formation of each of the first epitaxial pairs (201) of the epitaxial stack (200). Repeating each deposition cycle (103) a plurality of times, may thus, result in the formation of the epitaxial stack (200). The epitaxial stack (200) may, in other words, look like an epitaxial stack with alternating layers of the first epitaxial layer (201a) and the second epitaxial layer (201b). The number of times that each deposition cycle can be repeated may depend on the thickness of the eventual thickness of the epitaxial stack (200) to be obtained.

In embodiments, the order of the formation of the first epitaxial layer (201a) and the second epitaxial layer (201b) may differ depending on the substrate. Thus, in some embodiments, while the first epitaxial layer (201a) may be formed over the substrate, in some embodiments, the second epitaxial layer (201b) may be formed over the substrate.

In some embodiments, the first epitaxial layer (201a) may be formed directly on the substrate, while in some embodiments, the second epitaxial layer (201b) may be formed directly on the substrate as schematically represented in FIGS. 2a and 2b.

In some embodiments, during each deposition cycle (130), the first Group-IV semiconductor material precursor gas may be provided in a continuous flow to the process chamber and the second Group-IV semiconductor material precursor gas may be provided intermittently to the process chamber.

Provision of the first Group-IV semiconductor material precursor gas in a continuous flow may, in other words, mean that that it is provided during the first deposition pulse (131) and during the second deposition pulse (132). Accordingly, intermittent provision of the second Group-IV semiconductor material precursor gas may, in other words imply that it is provided only during the second deposition pulse (132).

This may provide the advantage of reducing the number of purge pulses when switching between the formation of the first epitaxial layer (201a) and the second epitaxial layer (201b).

In embodiments, the first Group-IV semiconductor material precursor gas that may be comprised in the first deposition pulse (131) for forming the first epitaxial layer (201a) may comprise substantially a second Si-containing precursor gas and the second Group-IV semiconductor material precursor gas that may further be comprised in the second deposition pulse (132), in addition to the first Group-IV semiconductor material precursor gas, for forming the second epitaxial layer (201b) may comprise substantially a Ge-containing precursor gas. In this way, a first epitaxial pair comprising a Si comprising first epitaxial layer (201a) and a Si₁₋ₓGeₓ comprising second epitaxial layer (201b) may be formed.

Formation of an epitaxial stack (200) having such epitaxial pairs of comprising the Si comprising first epitaxial layer (201a) and the Si₁₋ₓGeₓ comprising second epitaxial layer (201b) may be advantageous in the manufacturing of GAA-FET devices, particularly when the channel is in the form of a sheet, such as for example nanosheet-FET or CFET. After removal of the Si₁₋ₓGeₓ epitaxial layers from the first epitaxial pairs (201), Si epitaxial layer may form the channel of the p-MOS device and the n-MOS device of the FET.

In embodiments, the second Si-containing precursor gas may be a silane and the Ge-containing precursor gas may be a germane. This may advantageously allow for enhancing growth rate of the epitaxial layers at process temperatures lower than 600° C.

In some embodiments, the second Si-containing precursor gas may be a high order silane. Thus, in some embodiments, the second Si-containing precursor gas may be such as, for example, di-silane or tri-silane.

In some embodiments, the second Si-containing precursor gas may be di-silane and the Ge-containing precursor gas may be mono-germane.

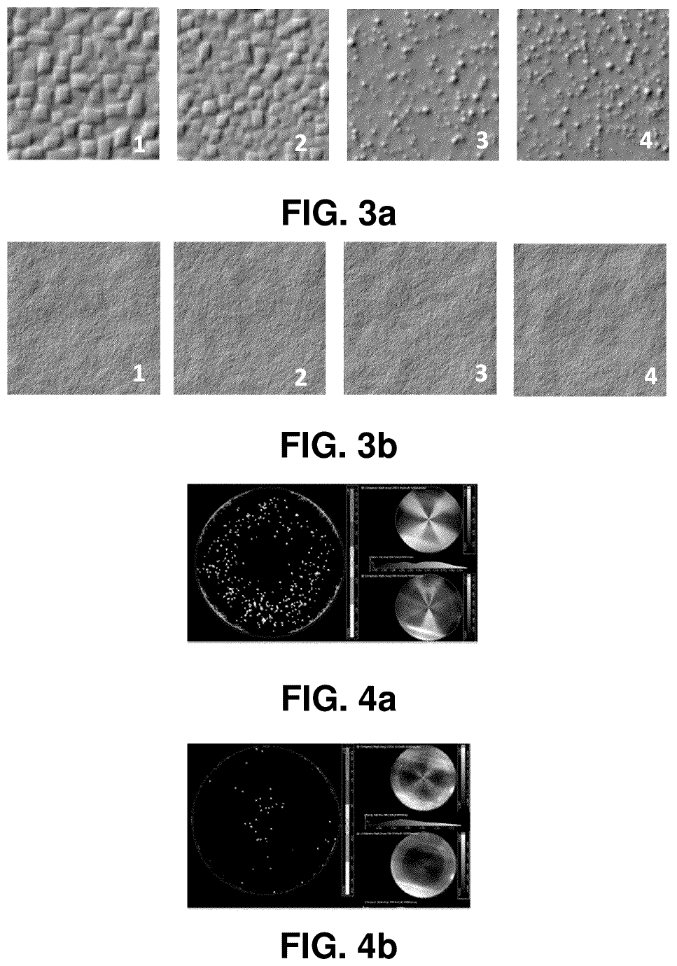

We return to FIG. 3a and FIG. 3b showing a comparison of a surface of Si₁₋ₓGeₓ epitaxial layer grown on Si(100) substrate as a function of differing process parameters, with the process temperature set to 490° C., wherein x represents Ge concentration in between 15 atomic % to 40 atomic %.

It is observed from FIG. 3a that the Si₁₋ₓGeₓ surface suffers from particle formation when the process pressure is set to 40 Torr. Increase of Si₂H₆ flow (going from image 1 to image 4 to the left) between 30 sccm up to 120 sccm with GeH₄ flow fixed at 800 sccm seemed to reduce particle formation, however, not removing the particles entirely from the epitaxial Si₁₋ₓGeₓ layer. Ge concentration in the Si₁₋ₓGeₓ layer is 34.6 atomic % and 29 atomic % in image 3 and 4, respectively.

It is observed in FIG. 3b that the surface of the Si₁₋ₓGeₓ epitaxial layer is free of particles when the process pressure is set to 3 Torr. SiH₄ flow rate is set to 40 sccm while GeH₄ flow is varied between 200 sccm up to 1600 sccm (going from image 1 to image 4 to the left). Ge concentration in the Si₁₋ₓGeₓ layer, going from image 1 to image 4 is, 15.3 atomic %, 21.7 atomic %, 32.1 atomic % and 40 atomic %.

Without wishing to be bound by theory, it may be stated that the formation of particles may be occurring due to the gas phase reaction typically occurring at temperatures in a range of 450° C. to 600° C. for obtaining Si₁₋ₓGeₓ/Si epitaxial stack of multiple layers of Si₁₋ₓGeₓ epitaxial layers formed alternatingly with Si epitaxial layers when the pressure is kept in a range between 20 Torr to 40 Torr. As the pressure is lowered the chance for the occurrence of such gas phase reactions may be reduced, thus, advantageously reducing particle formation.

It may further be an advantage of embodiments of the first aspect that a fully strained epitaxial stack of Si₁₋ₓGeₓ/Si epitaxial layers may be formed at lower process temperatures, such as for example, lower than 600° C. Having a fully strained epitaxial stack may provide the advantage of reducing the risk for dislocation. This may then advantageously allow for reducing dislocation density.

In embodiments, the second Si-containing precursor gas may be provided, to the process chamber, with a flow in a range of 30 sccm to 600 sccm and the Ge-containing precursor gas may be provided, to the process chamber, with a flow in a range of 100 sccm to 1600 sccm. The flow range for the second Si-containing precursor gas disclosed herein may be applicable both during the first deposition pulse (131) and during the second deposition pulse (132).

In embodiments, the flow of the second Si-containing precursor gas may be from at least 30 sccm to at most 100 sccm or from at least 100 sccm to at most 150 sccm or from at least 150 sccm to at most 200 sccm or from at least 200 sccm to at most 250 sccm or from at least 250 sccm to at most 300 sccm or from at least 300 sccm to at most 350 sccm or from at least 350 sccm to at most 400 sccm or from at least 400 sccm to at most 450 sccm or from at least 450 sccm to at most 500 sccm or from at least 500 sccm to at most 550 sccm or from at least 550 sccm to at most 600 sccm.

In embodiments, the flow of the Ge-containing precursor gas may be from at least 100 sccm to at most 200 sccm or from at least 200 sccm to at most 300 sccm or from at least 300 sccm to at most 400 sccm or from at least 400 sccm to at most 500 sccm or from at least 500 sccm to at most 600 sccm or from at least 600 sccm to at most 700 sccm or from at least 700 sccm to at most 800 sccm or from at least 800 sccm to at most 900 sccm or from at least 900 sccm to at most 1000 sccm or from at least 1000 sccm to at most 1100 sccm or from at least 1100 sccm to at most 1200 sccm or from at least 1200 sccm to at most 1300 sccm or from at least 1300 sccm to at most 1400 sccm or from at least 1400 sccm to at most 1500 sccm or from at least 1500 sccm to at most 1600 sccm.

It is to be noted that the flow of the Ge-containing precursor gas may be different depending on the Ge-containing precursor type. In some embodiments, the Ge-containing precursor may be a high order germane, such as for example di-germane, and the flow may be in a range of 5 sccm to 10 sccm.

In embodiments, the second Si-containing precursor gas may be provided with a flow in a range of 30 sccm to 100 sccm during the first deposition pulse (131) and in a range of 50 sccm to 100 scm during the second deposition pulse (132). The second Si-containing precursor gas, in these embodiments, may be di-silane.

In some embodiments, the flow of the second Si-containing precursor gas may be from at least 30 sccm to at most 40 sccm, or from at least 40 sccm to at most 50 sccm, or from at least 50 sccm to at most 60 sccm, or from at least 60 sccm to at most 70 sccm, or from at least 70 sccm to at most 80 sccm or from at least 80 sccm to at most 90 sccm, or from at least 90 sccm to at most 100 sccm.

In embodiments, adjusting the flow of di-silane may provide the advantage of further reducing particle formation.

We return to FIG. 4a and FIG. 4b showing a comparison of the light scattering images of the Si surface of the epitaxial stack.

It is observed from a comparison of the images that presence of particles on the surface has been reduced when di-silane flow is reduced from 600 sccm down to 100 sccm for forming the epitaxial layer. Thus, adjusting the flow of the second Si-containing precursor gas may advantageously allow for controlling particle formation on the surface of the epitaxial layer formed.

In some embodiments, a purge pulse may, nevertheless, be provided to the process chamber in between the formation of the individual epitaxial layers, i.e.: the in between the formation of the first epitaxial layer (201a) and the second epitaxial layer (201b) and in between the second epitaxial layer and the first epitaxial layer of the epitaxial stack (200). Accordingly, in these embodiments, the intermittent provision of the second Group-IV semiconductor material precursor gas is not be executed.

Thus, in some embodiments, each deposition cycle (130) may further comprise a purge pulse. The purge pulse may comprise providing a first Si-containing precursor gas and providing a hydrogen halide gas.

In embodiments, the provision of purge pulse (133) may be performed for a pre-determined duration before and after each deposition pulse (131, 132). Thus, the provision of the first Si-containing precursor gas and the provision of the hydrogen halide gas may be done before the first deposition pulse (131) and after the first deposition pulse (131) and after the second deposition pulse (132) of each deposition cycle (130). This may lead to performing the purge pulse (133) in between the formation of each of the individual epitaxial layers comprised in the epitaxial stack (200) as schematically represented in FIG. 1b.

In embodiments, the provision of the first Si-containing precursor gas and the provision of the hydrogen halide gas may be done during an overlapping period. In other words, the flow of the first Si-containing precursor gas and the flow of the hydrogen halide precursor gas may overlap with each other during a pre-defined period in the purge pulse. Thus, in embodiments, there may be a period during which, both of the first Si-containing precursor gas and the hydrogen halide precursor gas is being provided, at the same time, to the process chamber.

In some embodiments, the provision of the first Si-containing precursor gas may be done substantially simultaneously with the provision of the hydrogen halide gas. In other words, the first Si-containing precursor gas may be co-flown to the process chamber with the hydrogen halide gas. In yet other words, the first Si-containing precursor gas may be provided to the process chamber together with the hydrogen halide gas, such that the provision of the first Si-containing precursor gas and provision the hydrogen halide gas, to the process chamber starts and ends substantially at the same time.

Co-flowing the first Si-containing precursor gas with the hydrogen halide gas as disclosed herein may provide the advantage of obtaining a sharper interface between the different epitaxial layers, i.e.: in between the first epitaxial layer (201a) and the second epitaxial layer (201b) of the epitaxial stack (200). Co-flowing may particularly provide the advantage of reducing or substantially eliminating misfit dislocation density, which may be observed when growing an epitaxial stack (200), particularly an epitaxial stack (200) as disclosed herein.

In embodiments, the first Si-containing precursor gas and the hydrogen halide gas may comprise chlorine. The presence of chlorine may allow for creating a sharper interface in between the epitaxial layers during their formation in the epitaxial stack.

In embodiments, the first Si-containing precursor gas may be a chlorosilane.

In some embodiments, the chlorosilane may be di-chlorosilane (DCS).

In some embodiments, the purge pulse may thus comprise providing DCS and hydrogen chloride gas (HCl).

In some embodiments, flowing di-chlorosilane during the overlapping period with hydrogen chloride may be comprised in the provision of the purge gas.

In some embodiments, co-flowing di-chlorosilane with hydrogen chloride may be comprised in the provision of the purge gas.

In embodiments, a ratio of the flow of the first Si-containing precursor gas to the flow of the hydrogen halide gas may be about 1:1.

It is to be noted that the ratio of the flow between these two precursors may vary as long as a passivation effect rather than a deposition can be observed on the surface.

In embodiments, of the flow of the first Si-containing precursor gas to the flow of the hydrogen halide gas may be about 300 sccm.

In embodiments, the pre-determined duration for the provision of the purge gas to the process chamber may be about 5 seconds.

We now return to FIG. 2b showing a schematic drawing of an epitaxial stack according to an embodiment of the first aspect of the present disclosure.

In an embodiment, the epitaxial stack (300) may further comprise a second epitaxial pair (301). The second epitaxial pair (301) may be different than the first epitaxial pair (201). The epitaxial stack (300) may be formed on the substrate (210) with at least one second epitaxial pair (301) in between two neighboring first epitaxial pairs (201). This may provide the advantage of achieving selective etching between the different layers of the different epitaxial pairs of the epitaxial stack.

In embodiments, the second epitaxial pair (301) may comprise the first epitaxial layer (201a) and a third epitaxial layer (301b). The third epitaxial layer may comprise the at least first Group-IV semiconductor material. The third epitaxial layer (301b) may further comprise the second Group-IV semiconductor material. The plurality of the first epitaxial pairs (201) may have a first concentration of the second Group-IV semiconductor material and the third epitaxial layer (301b) may have a second concentration of the second Group-IV semiconductor material. The second concentration may be different than the first concentration.

The difference in the concentration of the second Group-IV semiconductor material comprised in the second epitaxial layer (201b) and in the third epitaxial layer (301b) may provide the advantage of being able to remove one of the second epitaxial layer (201b) or the third epitaxial layer (301b) selective to one another.

In embodiments, the epitaxial stack (300) may be formed in such a way that each of the second epitaxial layers (201b) and each of the third epitaxial layers (301b) are separated from another by the first epitaxial layer (201a) as schematically represented in FIG. 2b.

In embodiments, the second epitaxial layer (201b) and the third epitaxial layer (301b) may be referred to as a sacrificial layer of the first epitaxial pair (201) and of the second epitaxial pair (301), respectively. In other words, at least one of the second epitaxial layer (201b) and the third epitaxial layer (301b) may be removed from the epitaxial stack (200, 300) in one of the processing steps following the formation of the epitaxial stack.

In embodiments, the second concentration may be higher than the first concentration. This may allow for selectivity in removing third epitaxial layer with respect to the second epitaxial layer.

In embodiments, the first concentration of the second Group-IV semiconductor material may be in a range of about 10 atomic % to 25 atomic %. The second concentration of the second Group-IV semiconductor material may be in a range of about 30 atomic % to about 45 atomic %. It is to be noted that the value of the first concentration and the second concentration may change within the given concentration ranges. This may allow for tuning the etch selectivity when removing the third epitaxial layer with respect to the second epitaxial layer.

Thus, in embodiments, the first epitaxial layer (201a) of first epitaxial pair (201) may be a Si epitaxial layer and the second epitaxial layer (201b) of the first epitaxial pair (201) may be a Si₁₋ₓGeₓ epitaxial layer having the first concentration and the first epitaxial layer (201a) of second epitaxial pair (301) may be the Si epitaxial layer and the third epitaxial layer (301b) of the second epitaxial pair (301) may be a Si₁₋ₓGeₓ epitaxial layer having the second concentration.

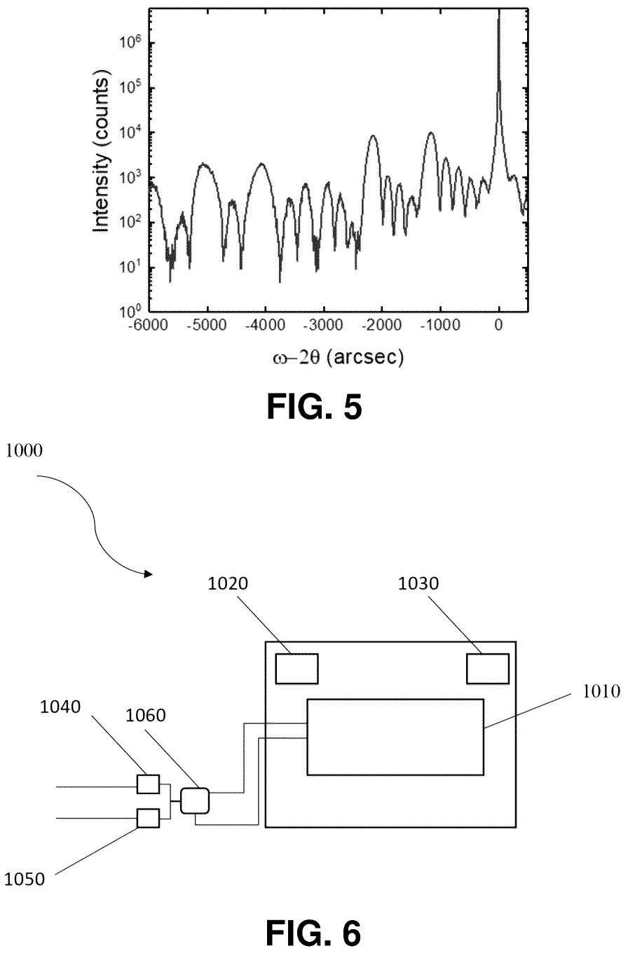

FIG. 5 shows a high Resolution X-Ray Diffraction (HR-XRD) graph for an epitaxial stack of Si₁₋ₓGeₓ/Si with Si₁₋ₓGeₓ epitaxial layers having a differing Ge concentration. Different Si₁₋ₓGeₓ epitaxial layers in the epitaxial stack (200) have a differing Ge concentration of 20 atomic % or 40 atomic %. It is observed from FIG. 5 from the peak shape and peak intensity that the epitaxial stack is not fully relaxed.

In embodiments, the thickness of each of the epitaxial layers (201a, 201b, 301b) may be the same or may be different from one another. The thickness of each epitaxial layer may be tailored according to the eventual use of the epitaxial stack (200, 300). The total thickness of the epitaxial stack (200, 300) may be a function of at least one of the total number of epitaxial pairs (201, 301) and the thickness of each of the epitaxial layers (201a, 201b, 301b).

In embodiments, each of the plurality of deposition cycles (130) may be performed at a temperature in a range of 450° C. to 600° C. This may provide the advantage of enabling growth of the epitaxial stack, as disclosed herein, at lower process temperatures. Therefore, it may allow for obtaining an epitaxial stack with a reduced risk for strain relaxation. When an epitaxial stack, as disclosed herein, is to be used for the manufacturing of semiconductor devices, the reduced risk for strain relaxation may provide the advantage of obtaining improved device characteristics such as for example, leakage current and threshold voltage. Furthermore, this may advantageously allow for keeping up with advanced CMOS (complementary metal oxide semiconductor) processing since epitaxial growth at lower process temperatures may become critical.

In embodiments, each of the plurality of deposition cycles (130) may be performed at a temperature in a range of from at least 450° C. to at most 475° C. or from at least 475° C. to at most 500° C. or from at least 500° C. to at most 525° C. or from at least 525° C. to at most 550° C. or from at least 550° C. to at most 575° C. or from at least 575° C. to at most 600° C.

In embodiments, the provision of the precursors disclosed herein may be provided in the presence of a carrier gas. In other words, the first deposition pulse (131) and the second deposition pulse (132) and the purge pulse (133) may further comprise providing the carrier gas. In embodiments, the carrier gas may comprise H₂ or N₂, and noble gases such as for example, Ar, Ne, He, Xe and Kr.

In some embodiments, the carrier gas may comprise substantially N₂, Ar, He or combinations thereof.

In some embodiments, the carrier gas may comprise substantially H₂, Ar, He. or combinations thereof.

Further described herein is a method of forming an epitaxial stack (200, 300).

The method may comprise providing a substrate to a process chamber. The process chamber may be comprised in a semiconductor processing apparatus. The semiconductor processing apparatus may be suitable for growing epitaxial layers.

In some embodiments, the process chamber may be one of at least two process chambers comprised in the semiconductor processing apparatus.

In some embodiments, the process chamber may be a single process chamber comprised in the semiconductor processing apparatus.

The method according to embodiments of the first aspect may be run in a single chamber; however, the same method may be run simultaneously in more than one process chamber of the semiconductor processing apparatus.

The method may further comprise performing a plurality of deposition cycles, thereby forming the epitaxial stack on the substrate.

The epitaxial stack may comprise a plurality of first epitaxial pairs. Each first epitaxial pair may comprise a first epitaxial layer and a second epitaxial layer. The first epitaxial layer and the second epitaxial layer of each first epitaxial pair may comprise at least a first Group-IV semiconductor material. The second epitaxial layer of each first epitaxial pair may further comprise a second Group-IV semiconductor material that may be different from the first semiconductor Group-IV semiconductor material. Each deposition cycle of the plurality of deposition cycles may comprise a first deposition pulse and a second deposition pulse, wherein each deposition cycle may further comprise a purge pulse before and after each deposition pulse and the purge pulse may comprise providing a first Si-containing precursor gas and providing a hydrogen halide gas.

The first deposition pulse, the second deposition pulse, the purge pulse may be done as disclosed herein according to embodiments of the first aspect of the present disclosure.

The method may be advantageous in lowering misfit dislocation density in the epitaxial films formed on the substrate. Furthermore, the method may advantageously allow for creating a sharp interface between the epitaxial layers of the epitaxial stack.

In embodiments, the process temperature may be in a range of 450° C. to 600° C.

Further described herein is a substrate processing apparatus as schematically shown in FIG. 6.

The substrate processing apparatus (1000) may be suitable for forming an epitaxial stack.

The substrate processing apparatus (1000) may comprise a process chamber (1010) that may be constructed and arranged to hold a substrate. The apparatus (1000) may further comprise a silicon precursor storage module (1040) and a germanium precursor storage module (1050). The silicon precursor storage module may comprise a Si-containing precursor, while the germanium precursor storage module may comprise a Ge-containing precursor. In embodiments, the number of the silicon precursor storage module (1040) or the number of the germanium precursor storage module (1050) may be increased depending on the number of different Si-containing or Ge-containing precursors to be used in the forming of the epitaxial stack.

The apparatus (1000) may also comprise a heater (1020) that may be configured to attain a process temperature in the process chamber (1010).

In some embodiments, the process temperature in the process chamber (1010) may be measured via a pyrometer. The pyrometer may be suspended in the process chamber (1010) above the substrate.

In some embodiments, the process temperature may be measured by using a thermocouple. The thermocouple may be positioned beneath a support, such as for example a susceptor, that supports the substrate in the process chamber (1010) during the process. It is to be noted that the substrate temperature measured by the pyrometer suspended above the substrate in the process chamber (1010) and that measured using a thermocouple may differ from each other, particularly at low process temperatures, such as for example, lower than 600° C. and particularly lower than 500° C.

It may further comprise a pressure controller (1030) that may be configured to attain a process pressure in the process chamber (1010).

The apparatus may further comprise a controller (1060). The controller (1060) may be operably connected to the silicon precursor storage module (1040) and to the germanium precursor storage module (1050). The controller may be con figured to execute instructions stored in a non-transitory computer readable medium to cause the substrate processing apparatus (1000) to form the epitaxial stack on the substrate in accordance with embodiments of the first aspect of the present disclosure.

The substrate processing apparatus (1000) may provide the advantage growing an epitaxial stack on a substrate. Particularly, growth of a fully strained Si₁₋ₓGeₓ/Si epitaxial stack on the substrate may be obtained, wherein x represents Ge concentration in between 10 atomic % to 50 atomic %.

The substrate processing apparatus (1000) may advantageously allow for growing the epitaxial stack with a reduced risk for process throughput loss. This may be achieved with the apparatus (1000) particularly at lower process temperatures, such as for example, lower than 600° C. In this way, the apparatus (1000) may contribute to the lowering of manufacturing costs for advanced CMOS manufacturing.

The embodiments of the present disclosure do not limit the scope of invention as these embodiments are defined by the claims appended herein and their legal equivalents. Any equivalent embodiments are intended to be within the scope of this invention. Modifications of the disclosure that are different from one another, in addition to those disclosed herein, may become apparent to those skilled in the art. Such modifications and the embodiments originating therefrom, are also intended to fall within the scope of the claims appended herein.

1. A method of forming an epitaxial stack, the method comprising:
providing a substrate to a process chamber,
performing a plurality of deposition cycles, thereby forming the epitaxial stack on the substrate, the epitaxial stack comprising a plurality of first epitaxial pairs, wherein each first epitaxial pair comprises a first epitaxial layer and a second epitaxial layer, wherein the first epitaxial layer and the second epitaxial layer of each first epitaxial pair comprises at least a first Group-IV semiconductor material and the second epitaxial layer of each first epitaxial pair further comprises a second Group-IV semiconductor material being different from the first Group-IV semiconductor material,
wherein each of the plurality of deposition cycles is performed at a pressure value of less than 10 Torr.

2. The method according to claim 1, wherein each of the plurality of deposition cycles is performed at a pressure value in a range of about 1 Torr to about 5 Torr.

3. The method according to claim 1, wherein each deposition cycle of the plurality of deposition cycles comprises:
a first deposition pulse comprising providing a first Group-IV semiconductor material precursor gas, thereby forming the first epitaxial layer, and
a second deposition pulse comprising providing the first Group-IV semiconductor material precursor gas and further comprising providing a second Group-IV semiconductor material precursor gas, thereby forming the second epitaxial layer, wherein the second Group-IV semiconductor material precursor gas is different from the first Group-IV semiconductor material precursor gas.

4. The method according to claim 1, wherein each deposition cycle further comprises a purge pulse comprising providing a first Si-containing precursor gas and providing a hydrogen halide gas.

5. The method according to claim 4, wherein the purge pulse is performed for a pre-determined duration before and after each deposition.

6. The method according to claim 4, wherein the provision of the first Si-containing precursor gas and the provision of the hydrogen halide gas is done during an overlapping period.

7. The method according to claim 4, wherein the first Si-containing precursor gas and the hydrogen halide gas comprises chlorine.

8. The method according to claim 4, wherein the first Si-containing precursor gas is a chlorosilane.

9. The method according to claim 4, wherein the first Si-containing precursor gas is di-chlorosilane and the hydrogen halide gas is hydrogen chloride.

10. The method according to claim 4, wherein a ratio of flow of the first Si-containing precursor gas to flow of the hydrogen halide gas is about 1:1.

11. The method according to claim 10, wherein the flow of the first Si-containing precursor gas and the flow of the hydrogen halide gas is about 300 sccm.

12. The method according to claim 5, wherein the pre-determined duration is about 5 seconds.

13. The method according to claim 3, wherein during each deposition cycle the first Group-IV semiconductor material precursor gas is provided in a continuous flow and wherein the second Group-IV semiconductor material precursor gas is provided intermittently.

14. The method according to claim 3, wherein the first Group-IV semiconductor material precursor gas comprises substantially a second Si-containing precursor gas and the second Group-IV semiconductor material precursor gas comprises substantially a Ge-containing precursor gas.

15. The method according to claim 14, wherein the second Si-containing precursor gas is a silane and the Ge-containing precursor gas is a germane.

16. The method according to claim 14, wherein the second Si-containing precursor gas is di-silane and the Ge-containing precursor gas is mono-germane.

17. The method according to claim 16, wherein the second Si-containing precursor gas is provided with a flow in a range of 30 sccm to 600 sccm and the Ge-containing precursor gas is provided with a flow in a range of 100 sccm to 1600 sccm.

18. The method according to claim 17, wherein the second Si-containing precursor gas is provided with a flow in a range of 30 sccm to 100 sccm during the first deposition pulse and in a range of 50 sccm to 100 sccm during the second deposition pulse.

19. The method according to claim 1, wherein the epitaxial stack further comprises a second epitaxial pair, the second epitaxial pair being different than the first epitaxial pair and wherein the epitaxial stack is formed on the substrate with at least one second epitaxial pair being in between two neighboring first epitaxial pairs.

20. The method according to claim 19, wherein the second epitaxial pair comprises the first epitaxial layer and a third epitaxial layer, the third epitaxial layer comprising the at least first Group-IV semiconductor material and further comprising the second Group-IV semiconductor material, wherein the plurality of the first epitaxial pairs has a first concentration of the second Group-IV semiconductor material and a third epitaxial pair has a second concentration of the second Group-IV semiconductor material, the second concentration being different than the first concentration.
